(19) United States
(12) Patent Application Publication
(10) Pub. No.: US 2009/0242250 A1
(43) Pub. Date: Oct. 1, 2009

(54) POLYIMIDE FILM, METHOD FOR PRODUCTION THEREOF, POLYIMIDE-METAL LAMINATED PRODUCT, AND CIRCUIT BOARD

(75) Inventors: Masafumi KOHDA, Ube-shi (JP); Hiroaki YAMAGUCHI, Ube-shi (JP); Toshifumi YAMANE, Ichihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: UBE INDUSTRIES, LTD., Ube-shi (JP)

(21) Appl. No.: 12/413,917

(22) Filed: Mar. 30, 2009

(30) Foreign Application Priority Data
Mar. 31, 2008 (JP) 2008-094198
Feb. 17, 2009 (JP) 2009-033775

(51) Int. Cl. H05K 1/03; B32B 15/08; B32B 37/12; C25D 5/00; B05D 3/02; B32B 27/06

(52) U.S. Cl. 174/259; 428/458; 156/60; 205/80; 427/384; 428/473.5

(57) ABSTRACT

Disclosed is a polyimide film produced by heating a self-supporting film of a polyimide precursor solution onto which a solution containing an aluminum chelate compound and, optionally, a nonionic surfactant and/or an aluminum alcoholate compound having at least one alkoxy group is applied to effect imidization.

### TECHNICAL FIELD

The present invention relates to a polyimide film having an improved adhesiveness and an excellent surface smoothness, and a method for producing the polyimide film. The present invention also relates to a polyimide-metal laminated product comprising the polyimide film, and a polyimide circuit board produced from the polyimide-metal laminated product.

### BACKGROUND ART

A polyimide film is widely used in electronic device applications because it has high heat resistance and excellent electric properties.

However, a polyimide film may not have sufficiently adhesive properties. When a metal foil such as a copper foil is bonded onto a polyimide film with a heat-resistant adhesive such as an epoxy resin adhesive, high adhesive strength may not be achieved. Furthermore, a laminate having high peel strength may not be obtained when a metal layer is formed on a polyimide film by vapor deposition or sputtering.

As a polyimide film having an improved adhesive property including sputtering property (suitability for sputtering) and metal vapor deposition property (suitability for metal vapor deposition) while maintaining the excellent properties of a polyimide film, Patent document 1 discloses a polyimide film prepared by drying and heating a self-supporting film obtained from an polyamic acid solution onto which an aluminum-containing compound solution is applied to a temperature of 420° C. or higher to effect imidization, and having an aluminum content of the film surface of 1 ppm to 1000 ppm.

In addition, Patent document 1 also discloses a laminate obtained by bonding a metal foil to one side or both sides of the polyimide film wherein the aluminum content of the film surface is within a range of 1 ppm to 1000 ppm as described above, with a heat-resistant adhesive. Patent document 2 discloses a laminate obtained by forming a metal layer or a metal oxide layer directly on one side or both sides of a polyimide film wherein the aluminum content of the film surface is within a range of 1 ppm to 1000 ppm by vapor deposition or sputtering, for example. Patent document 3 discloses a polyimide-metal laminate obtained by forming a metal conductive layer by a wet plating process on a polyimide film prepared by drying and heating a self-supporting film obtained from an polyamic acid solution onto which an aluminum-containing compound solution is applied to a temperature of 420° C. or higher to effect imidization. Patent document 3 also discloses a polyimide circuit board obtained by forming a circuit on the polyimide-metal laminate.

### CITATION LIST

Patent document 1: Japanese Laid-open Patent Publication No. 1999-158276;

Patent document 2: Japanese Laid-open Patent Publication No. 1999-240106;

Patent document 3: Japanese Laid-open Patent Publication No. 2005-225228.

### SUMMARY OF INVENTION

An objective of the present invention is to provide a polyimide film having excellent adhesive properties, sputtering property, metal vapor deposition property and metal plating property, and excellent surface smoothness, while maintaining the excellent properties of a polyimide film. Another objective of the present invention is to provide a polyimide-metal laminated product comprising the polyimide film, and a polyimide circuit board produced from the polyimide-metal laminated product.

The present invention relates to the followings.

[1] A process for producing a polyimide film, comprising steps of:

providing a self-supporting film of a polyimide precursor solution;

applying a solution containing an aluminum chelate compound onto one side or both sides of the self-supporting film; and

heating the self-supporting film onto which the aluminum chelate compound solution is applied to effect imidization; wherein

the aluminum chelate compound is a compound represented by the formula (1):

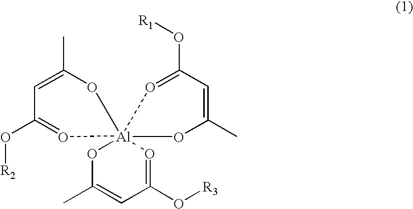

wherein
R₁, R₂ and R₃ independently represent a linear or branched alkyl group having 1 to 8 carbon atoms.

[2] The process for producing a polyimide film as described in [1], wherein the aluminum chelate compound solution to be applied onto one side or both sides of the self-supporting film contains a nonionic surfactant.

[3] The process for producing a polyimide film as described in [2], wherein the nonionic surfactant contained in the aluminum chelate compound solution is at least one selected from the group consisting of silicone surfactants and polyethylene glycol surfactants.

[4] The process for producing a polyimide film as described in [1], wherein the aluminum chelate compound solution to be applied onto one side or both sides of the self-supporting film contains an aluminum alcoholate compound having at least one alkoxy group.

[5] The process for producing a polyimide film as described in [4], wherein the aluminum alcoholate compound contained in the aluminum chelate compound solution is a compound represented by the formula (2):

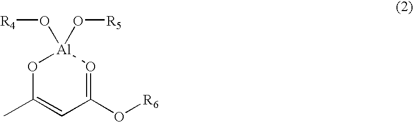

wherein
R₄ and R₅ independently represent a linear or branched alkyl group having 1 to 6 carbon atoms, and
R₆ represents a linear or branched alkyl group having 1 to 8 carbon atoms.

[6] The process for producing a polyimide film as described in [4], wherein the aluminum alcoholate compound contained in the aluminum chelate compound solution is aluminum ethylacetoacetate diisopropylate.

[7] The process for producing a polyimide film as described in any one of [1] to [6], wherein the aluminum chelate compound is aluminum tris(ethylacetoacetate).

[8] The process for producing a polyimide film as described in any one of [1] to [7], wherein the self-supporting film is heated to the highest heating temperature of from 350° C. to 520° C. for imidization.

[9] A polyimide film produced by the process as described in any one of [1] to [8].

[10] A polyimide film wherein the aluminum content of at least one surface of the polyimide film is within a range of 0.1% to 52%; and reticulated irregularities is not observed in the surface with an optical microscope at a magnification of 500 times.

[11] A polyimide-metal laminated product wherein a metal layer is formed on the surface of the polyimide film as described in [9] onto which a solution containing an aluminum chelate compound represented by the formula (1) is applied in producing the polyimide film.

[12] The polyimide-metal laminated product as described in [11], wherein the metal layer is formed on the polyimide film by adhering a metal foil with an adhesive.

[13] The polyimide-metal laminated product as described in [11], wherein the metal layer is formed on the polyimide film by a dry plating process or a wet plating process.

[14] A circuit board obtained by forming a circuit on the polyimide-metal laminated product as described in any one of [11] to [13].

[15] The circuit board as described in [14], wherein the circuit board comprises a metal wiring with a pitch of 30 μm or less.

According to the present invention, a solution containing an aluminum chelate compound represented by the above formula (1), preferably a solution containing an aluminum chelate compound represented by the above formula (1) and a nonionic surfactant or an aluminum alcoholate compound having at least one alkoxy group, is applied to one side or both sides of a self-supporting film of a polyimide precursor solution, and then the self-supporting film is heated to effect imidization. The aluminum chelate-modified surface (surface to which a solution containing an aluminum chelate compound represented by the formula (1) is applied) of the polyimide film thus obtained has improved adhesive properties, sputtering property, metal vapor deposition property and metal plating property, and has excellent surface smoothness. When applying a solution containing an aluminum chelate compound represented by the above formula (1) to a self-supporting film of a polyimide precursor solution, adhesive properties of the polyimide film obtained may be remarkably improved. Furthermore, when using a nonionic surfactant and/or an aluminum alcoholate compound having at least one alkoxy group, in addition to an aluminum chelate compound represented by the formula (1), the solution may be applied more evenly and more easily to a self-supporting film of a polyimide precursor solution, and therefore the aluminum chelate-modified surface of the polyimide film obtained may be smoother.

A metal foil may be attached onto the aluminum chelate-modified surface of the polyimide film of the present invention with an adhesive, to give a polyimide-metal laminated product having excellent adhesiveness and sufficiently high peel strength. Alternatively, a metal layer may be formed on the aluminum chelate-modified surface of the polyimide film of the present invention by a dry plating process (metal vapor deposition or sputtering, for example) or a wet plating process, to give a polyimide-metal laminated product having excellent adhesiveness and sufficiently high peel strength.

Furthermore, a circuit board may be obtained from the polyimide-metal laminated product of the present invention by forming a circuit by a subtractive process or a semi-additive process. As described above, the polyimide film of the present invention has the smooth aluminum chelate-modified surface. Therefore, a fine metal wiring with a pitch of 30 μm or less, further 20 μm or less, may be formed on the polyimide film of the present invention without a faulty connection. The surface smoothness of the polyimide film to be used is more required for the formation of such a fine-pitch wiring. For example, when using a polyimide film having reticulated irregularities on the surface, a metal may remain or be removed along the irregularities, and a good fine-pitch wiring may not be formed.

### BRIEF DESCRIPTION OF THE DRAWINGS

FIG. 1 is a diagram showing an example of the typical process for producing a polyimide-metal laminated product of the invention by a wet plating process.

FIG. 2 is a diagram showing a first stage in an example of the typical process for producing a polyimide double-sided circuit board of the invention.

FIG. 3 is a diagram showing a second stage in the example of the typical process for producing a polyimide double-sided circuit board of the invention.

FIG. 4 is a diagram showing a third stage in the example of the typical process for producing a polyimide double-sided circuit board of the invention.

FIG. 5 is an electron microscope photograph of the aluminum chelate-modified surface of the polyimide film prepared in Example 1.

FIG. 6 is an electron microscope photograph of the aluminum chelate-modified surface of the polyimide film prepared in Comparative Example 1.

### DESCRIPTION OF THE MAIN SYMBOLS

101: polyimide film having an aluminum chelate-modified surface,
102: catalyst for formation of a ground layer,
103: zinc-containing indium hydroxide ground layer formed by electroless plating,
104: catalyst for electroless copper plating,
105: electrode layer for electrolytic copper plating,
106: conductive metal layer formed by electrolytic copper plating,
206: through-hole for front/back conduction,
207: dry film type negative photoresist,
208: section in which a circuit is not formed,
209: conductive layer formed by electrolytic copper plating.

### DESCRIPTION OF EMBODIMENTS

According to the present invention, a solution containing an aluminum chelate compound represented by the above formula (1), preferably a solution containing an aluminum chelate compound represented by the above formula (1) and a nonionic surfactant or an aluminum alcoholate compound having at least one alkoxy group, is applied to one side or both sides of a self-supporting film of a polyimide precursor solution, and then the self-supporting film is heated to effect imidization, thereby forming a polyimide film.

A self-supporting film of a polyimide precursor solution may be prepared by flow-casting a solution of a polyimide precursor in an organic solvent to give a polyimide on a support, after adding an imidization catalyst, an organic phosphorous compound and/or an inorganic fine particle to the solution, if necessary, and then heating it sufficiently to make it self-supporting, which means a stage before a common curing process.

A preferable polyimide precursor may be prepared from an aromatic tetracarboxylic dianhydride and an aromatic diamine.

Specifically, preferred is a polyimide precursor prepared from 3,3′,4,4′-biphenyltetracarboxylic dianhydride (hereinafter, sometimes abbreviated as “BPDA”), p-phenylenediamine (hereinafter, sometimes abbreviated as “PPD”) and optionally 4,4′-diaminodiphenyl ether (hereinafter, sometimes abbreviated as “DADE”). In this case, a ratio of PPD/DADE (molar ratio) is preferably 100/0 to 85/15.

And also, preferred is a polyimide precursor prepared from pyromellitic dianhydride (hereinafter, sometimes abbreviated as “PMDA”), or an aromatic tetracarboxylic dianhydride consisting of 3,3′,4,4′-biphenyltetracarboxylic dianhydride and pyromellitic dianhydride, and an aromatic diamine such as benzene diamine and biphenyldiamine. The aromatic diamine may be preferably p-phenylenediamine, an aromatic diamine in which a ratio of PPD/DADE is 90/10 to 10/90, or tolidine (ortho- and meta-types). In this case, a ratio of BPDA/PMDA is preferably 0/100 to 90/10.

In addition, preferred is a polyimide precursor prepared from pyromellitic dianhydride, p-phenylenediamine and 4,4′-diaminodiphenyl ether. In this case, a ratio of DADE/PPD is preferably 90/10 to 10/90.

A polyimide precursor may be synthesized by random-polymerizing or block-polymerizing substantially equimolar amounts of an aromatic tetracarboxylic dianhydride and an aromatic diamine in an organic solvent. Alternatively, two or more polyimide precursor solutions in which either of these two components is excessive may be prepared, and subsequently, these polyimide precursor solutions may be combined and then mixed under the reaction conditions. The polyimide precursor solution thus obtained may be used without any treatment, or may be used after removing or adding a solvent, if necessary, to prepare a self-supporting film.

Examples of an organic solvent for the polyimide precursor solution include N-methyl-2-pyrrolidone, N,N-dimethylformamide, N,N-dimethylacetamide and N,N-diethylacetamide. These organic solvents may be used alone or in combination of two or more.

The polyimide precursor solution may contain an imidization catalyst, an organic phosphorous-containing compound, an inorganic fine particle, and the like, if necessary. The polyimide precursor solution preferably contains an imidization catalyst.

Examples of the imidization catalyst include substituted or unsubstituted nitrogen-containing heterocyclic compounds, N-oxide compounds of the nitrogen-containing heterocyclic compounds, substituted or unsubstituted amino acid compounds, hydroxyl-containing aromatic hydrocarbon compounds, and aromatic heterocyclic compounds. Particularly suitable examples of the imidization catalyst include lower-alkylimidazoles such as 1,2-ddimethylimidazole, N-methylimidazole, N-benzyl-2-methylimidazole, 2-methylimidazole, 2-ethyl-4-imidazole and 5-methylbenzimidazole; benzimidazoles such as N-benzyl-2-methylimidazole; and substituted pyridines such as isoquinoline, 3,5-dimethylpyridine, 3,4-dimethylpyridine, 2,5-dimethylpyridine, 2,4-dimethylpyridine and 4-n-propylpyridine. The amount of the imidization catalyst used is preferably about 0.01 to 2 equivalents, particularly preferably about 0.02 to 1 equivalents relative to the amount of an amide acid unit in a polyamide acid. When the imidization catalyst is used, the polyimide film obtained may have the improved properties, particularly extension and edge-cracking resistance.

Examples of the organic phosphorous-containing compound include phosphates such as monocaproyl phosphate, monooctyl phosphate, monolauryl phosphate, monomyristyl phosphate, monocetyl phosphate, monostearyl phosphate, triethyleneglycol monotridecyl ether monophosphate, tetraethyleneglycol monolauryl ether monophosphate, diethyleneglycol monostearyl ether monophosphate, dicaproyl phosphate, dioctyl phosphate, dicapryl phosphate, dilauryl phosphate, dimyristyl phosphate, dicetyl phosphate, distearyl phosphate, tetraethyleneglycol mononeopentyl ether diphosphate, triethyleneglycol monotridecyl ether diphosphate, tetraethyleneglycol monolauryl ether diphosphate, and diethyleneglycol monostearyl ether diphosphate; and amine salts of these phosphates. Examples of the amine include ammonia, monomethylamine, monoethylamine, monopropylamine, monobutylamine, dimethylamine, diethylamine, dipropylamine, dibutylamine, trimethylamine, triethylamine, tripropylamine, tributylamine, monoethanolamine, diethanolamine and triethanolamine.

Examples of the inorganic fine particle include particulate inorganic oxide powders such as titanium dioxide powder, silicon dioxide (silica) powder, magnesium oxide powder, aluminum oxide (alumina) powder and zinc oxide powder; particulate inorganic nitride powders such as silicon nitride powder and titanium nitride powder; inorganic carbide powders such as silicon carbide powder; and particulate inorganic salt powders such as calcium carbonate powder, calcium sulfate powder and barium sulfate powder. These inorganic fine particles may be used alone or in combination of two or more. These inorganic fine particles can be homogeneously dispersed using a known method.

A self-supporting film of a polyimide precursor solution is prepared by flow-casting and applying the above-mentioned solution of a polyimide precursor in an organic solvent, or a polyimide precursor solution composition which is prepared by adding an imidization catalyst, an organic phosphorous-containing compound, an inorganic fine particle, and the like to the above solution, on a support; and then heating it to the extent that the film becomes self-supporting, which means a stage before a common curing process, for example, to the extent that the film can be peeled from the support. For example, a film of a polyimide precursor solution, which is flow-casted on a support, is heated at a temperature of 100° C. to 180° C. for about 2 min to 60 min. The content of the polyimide precursor in the polyimide precursor solution may be preferably about 10 wt % to 30 wt %. The polyimide precursor solution may preferably have a polymer concentration of about 8 wt % to 25 wt %. The support used may be a stainless substrate or a stainless belt, for example.

In the present invention, an aluminum chelate compound solution should be substantially uniformly, preferably uniformly and evenly, applied to one side or both sides of a peeled self-supporting film. Thus, the self-supporting film should be a film to one side or both sides of which an aluminum chelate compound solution can be applied substantially uniformly, preferably uniformly and evenly. Accordingly, the heating conditions such as a heating temperature and a heating time should be appropriately selected to give such a film. For preparing such a film, it is necessary to control the amount of the solvent contained in the self-supporting film and imidization of the polyimide precursor.

It is preferable that a weight loss on heating of a self-supporting film is within a range of 20 wt % to 40 wt %; and it is further preferable that a weight loss on heating of a self-supporting film is within a range of 20 wt % to 40 wt % and an imidization rate of a self-supporting film is within a range of 8% to 40%. When the weight loss on heating and the imidization rate are within the above range, the self-supporting film obtained has sufficient mechanical properties, an aluminum chelate compound solution is applied to the surface of the self-supporting film more evenly and more easily, and no foaming, flaws, crazes, cracks and fissures are observed in the polyimide film obtained after imidization.

The weight loss on heating of a self-supporting film as described above is calculated by the following numerical equation from the weight before drying (W1) and the weight after drying (W2) of the film to be measured which is dried at 420° C. for 20 min.

Weight loss on heating (% by weight)={(W1−W2)/W1}×100

The imidization rate of a self-supporting film as described above can be determined in accordance with the procedure described in Japanese Laid-open Patent Publication No. 1997-316199, using a Karl Fischer moisture meter. For example, the imidization rate can be calculated based on the ratio of the vibration band peak area measured by IR spectrometer (ATR) between the film and a fully-cured product. The vibration band peak utilized in the procedure may include a symmetric stretching vibration band of an imide carbonyl group and a stretching vibration band of a benzene ring skeleton.

According to the present invention, a solution containing an aluminum chelate compound represented by the following formula (1), preferably a solution containing an aluminum chelate compound represented by the following formula (1) and a nonionic surfactant and/or an aluminum alcoholate compound having at least one alkoxy group, is applied to one side or both sides of the self-supporting film thus obtained.

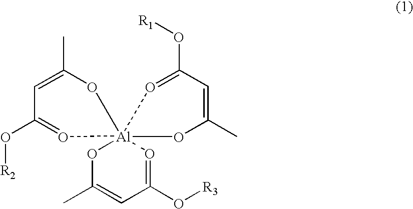

In the formula (1), R₁, R₂ and R₃ independently represent a linear or branched alkyl group having 1 to 8 carbon atoms. R₁, R₂ and R₃ may be the same as, or different from each other.

R₁, R₂ and R₃ are preferably a linear or branched alkyl group having 2 to 4 carbon atoms, more preferably ethyl or isobutyl, particularly preferably ethyl.

Specific examples of the aluminum chelate compound represented by the formula (1) include compounds represented by the formula (1) in which R₁, R₂ and R₃ each are a linear or branched alkyl group having 1 to 8 carbon atoms, for example, aluminum tris(ethylacetoacetate), aluminum tris(methylacetoacetate), aluminum tris(sec-butylacetoacetate), aluminum tris(hexylacetoacetate) and aluminum tris(iso-octylacetoacetate). A commercially available aluminum chelate compound such as ALCH-TB made by Kawaken Fine Chemicals Co., Ltd., (aluminum chelate compound represented by the formula (1) in which R₁, R₂ and R₃ are ethyl or isobutyl) may be used.

The aluminum chelate compounds may be used alone or in combination of two or more.

The aluminum chelate compound solution used in the present invention may contain a nonionic surfactant. There are no particular restrictions to the nonionic surfactant used in the present invention, so long as it is soluble in the organic solvent used and decomposes/volatilizes by heat treatment for imidization.

Preferable examples of the nonionic surfactant include silicone surfactants and polyethylene glycol surfactants. A particularly preferable surfactant may be a silicone surfactant. The high surface smoothness of the aluminum chelate-modified surface may be achieved by a smaller amount of a silicone surfactant, as compared to a polyethylene glycol surfactant.

As a silicone surfactant, silicone oil may be used, and modified silicone oil in which an organic group such as phenyl substitutes for a part of the methyl group may be also used.

Silicone surfactants are commercially available. For example, L77, FZ-2105, FZ-2123, FZ-2118, L7604, L7002, FZ-2120, FZ-2101, FZ-3196 and L7001 made by Dow Corning Toray Co., Ltd., and the like may be used.

A preferable polyethylene glycol surfactant may be a relatively low molecular weight polyethylene glycol surfactant, in view of the solvent solubility. More specifically, a polyethylene glycol surfactant may preferably have a molecular weight of 1000 or less. For example, ethylene glycol may be suitably used.

The nonionic surfactants may be used alone or in combination of two or more.

The aluminum chelate compound solution used in the present invention may contain an aluminum alcoholate compound having at least one alkoxy group.

The aluminum alcoholate compound used in the present invention has at least one alkoxy group, preferably one or two alkoxy groups. There are no particular restrictions to the aluminum alcoholate compound, so long as it is soluble in the organic solvent used.

A preferable aluminum alcoholate compound may be an aluminum dialcoholate compounds represented by the following formula (2).

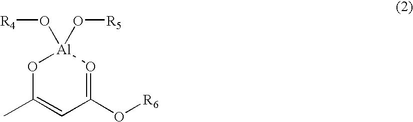

In the formula (2), R₄ and R₅ independently represent a linear or branched alkyl group having 1 to 6 carbon atoms. R₄ and R₅ may be the same as, or different from each other. R₄ and R₅ are preferably a linear or branched alkyl group having 1 to 4 carbon atoms, more preferably ethyl, isopropyl or isobutyl, particularly preferably isopropyl.

In the formula (2), R₆ represents a linear or branched alkyl group having 1 to 8 carbon atoms. R₆ is preferably a linear or branched alkyl group having 1 to 4 carbon atoms, more preferably ethyl, isopropyl or isobutyl, particularly preferably ethyl.

Specific examples of the aluminum alcoholate compound include aluminum ethylacetoacetate diisopropylate, aluminum butylacetoacetate diisopropylate, aluminum hexylacetoacetate diisopropylate, aluminum octylacetoacetate diisopropylate, aluminum ethylacetoacetate hexylate isopropylate, aluminum hexylacetoacetate diisobutylate, and aluminum benzylacetoacetate diisopropylate.

The aluminum alcoholate compounds may be used alone or in combination of two or more.

The aluminum chelate compound solution used in the present invention may contain one or more nonionic surfactants and one or more aluminum alcoholate compounds having at least one alkoxy group.

The organic solvent for the aluminum chelate compound solution to be applied to a self-supporting film of a polyimide precursor solution (application solution) may be selected from those in which the aluminum chelate compound to be used is soluble, more preferably the aluminum chelate compound and the nonionic surfactant and/or the aluminum alcoholate compound to be used are soluble. Examples of the organic solvent for the aluminum chelate compound solution may include those listed as the organic solvent for the polyimide precursor solution (the solvent contained in the self-supporting film), for example, N,N-dimethylacetamide. In addition, an alcohol such as isopropyl alcohol (preferably an alcohol of a linear or branched alkyl group having 1 to 5 carbon atoms, more preferably 1 to 4 carbon atoms), an aromatic hydrocarbon, an aliphatic hydrocarbon, an alicyclic hydrocarbon, a ketone, or an ether may be also used. The preferable organic solvent is a solvent compatible with the polyimide precursor solution, and is the same as the organic solvent for the polyimide precursor solution. The organic solvent may be a mixture of two or more compounds.

The concentration of the aluminum chelate compound in the application solution may be preferably about 0.01 wt % to about 10 wt %, more preferably about 0.02 wt % to about 7 wt %, further preferably about 1 wt % to about 6 wt %, particularly preferably about 2 wt % to about 5 wt %. When the concentration of the aluminum chelate compound is less than 0.01 wt %, the sufficient effect of improving adhesiveness may not be obtained. On the other hand, when the concentration of the aluminum chelate compound is excessively high, the polyimide film obtained may be inferior in properties.

If a silicone surfactant is used, the concentration of the silicone surfactant in the application solution may be preferably about 10 ppm to about 10000 ppm, more preferably about 20 ppm to about 2000 ppm. If a polyethylene glycol surfactant is used, the concentration of the polyethylene glycol surfactant in the application solution may be preferably about 0.1% to about 40%, more preferably about 1% to about 20%. When the concentration of the nonionic surfactant is less than the above value, i.e. 10 ppm (silicone surfactant) or 0.1% (polyethylene glycol surfactant), the sufficient effect of improving surface smoothness may not be obtained. On the other hand, when the concentration of the nonionic surfactant is excessively high, the surface smoothness of the polyimide film obtained may be deteriorated.

If an aluminum alcoholate compound is used, the concentration of the aluminum alcoholate compound in the application solution may be preferably about 0.1 parts by weight to about 20 parts by weight, more preferably about 0.5 parts by weight to about 10 parts by weight, particularly preferably about 1 parts by weight to about 8 parts by weight, relative to 100 parts by weight of the aluminum chelate compound. When the concentration of the aluminum alcoholate compound is less than the above value, i.e. 0.1 parts by weight, the sufficient effect of improving surface smoothness may not be obtained. On the other hand, when the concentration of the aluminum alcoholate compound is excessively high, the surface smoothness of the polyimide film obtained may be deteriorated.

The application solution may contain other additive components, as long as the characteristics of the present invention would not be impaired.

The amount of the aluminum chelate compound solution to be applied to a self-supporting film of a polyimide precursor solution may be appropriately determined and, for example, it is preferably 1 to 50 g/m², more preferably 2 to 30 g/m², particularly preferably 3 to 20 g/m² for both the side of the self-supporting film which was in contact with the support and the opposite side. The application amount of the aluminum chelate compound solution to one side may be the same as, or different from the application amount of the aluminum chelate compound solution to the other side.

The aluminum chelate compound solution may be applied by any known method; for example, by gravure coating, spin coating, silk screen coating, dip coating, spray coating, bar coating, knife coating, roll coating, blade coating, and die coating.

According to the present invention, the self-supporting film onto which an aluminum chelate compound solution is applied is then heated to effect imidization, thereby producing a polyimide film.

The heating temperature for imidization may be preferably 350° C. to 520° C., more preferably 380° C. to 500° C. When the heating temperature for imidization is higher than 520° C., the polyimide-metal laminated product wherein a metal layer is formed on the polyimide film obtained by a wet plating process may not have sufficiently high strength of the metal layer.

The preferable heat treatment may be a process in which polymer imidization and solvent evaporation/removal are gradually conducted at about 100° C. to 400° C. for about 0.05 hours to 5 hours, particularly 0.1 hours to 3 hours as the first step. This heat treatment is particularly preferably conducted stepwise, that is, the first heat treatment at a relatively lower temperature of about 100° C. to 170° C. for about 0.5 min to 30 min, then the second heat treatment at a relatively higher temperature of 170° C. to 350° C. for about 0.5 min to 30 min, and then the third heat treatment at a high temperature of 350° C. to 520° C. (highest heating temperature). In continuous heat treatment at 170° C. or higher, it is preferable to fix at least both edges of a long solidified film in the direction perpendicular to the length direction, i.e. in the width direction, with a pintenter, a clip or a frame, for example, while heating. When producing a thin polyimide film, the heat treatment may be conducted for a relatively short time.

Although there are no particular restrictions to the thickness of the polyimide film obtained according to the present invention, it may be 150 μm or less, preferably 5 μm to 120 μm, for example.

According to the present invention, there may be provided, for example, a polyimide film wherein the aluminum content of at least one surface is within a range of 0.1% to 52%, preferably 1% to 20%, more preferably 3% to 15%, particularly preferably 4% to 9% in terms of aluminum atom or aluminum metal; the surface of the aluminum chelate-modified surface is smooth, and characteristic reticulated irregularities is not observed in the surface with an optical microscope at a magnification of 500 times. When the aluminum content of the polyimide film surface is less than 0.1%, the polyimide film obtained may not have sufficient adhesive properties. When the aluminum content of the polyimide film surface is more than 52%, the polyimide film obtained may not have sufficient mechanical properties and adhesive properties.

The aluminum content of a surface of a polyimide film may be measured by a scanning X-ray photoelectron spectrometer.

The polyimide film of the present invention may preferably have a thermal expansion coefficient (50 to 200° C.) of from 5×10⁻⁶ cm/cm/° C. to 25×10⁻⁶ cm/cm/° C.

A polyimide film obtained according to the present invention has excellent adhesive properties, sputtering property, metal vapor deposition property and metal plating property. Therefore, a polyimide-metal laminated product having excellent adhesiveness and sufficiently high peel strength, for example, a polyimide-metal laminated product having a 90 peel strength of 0.1 N/mm or higher may be obtained by bonding a metal foil to the aluminum chelate-modified surface (surface to which a solution containing an aluminum chelate compound represented by the formula (1) is applied) of the polyimide film with an adhesive; or alternatively, by forming a metal layer on the aluminum chelate-modified surface of the polyimide film by a dry plating process (metal vapor deposition or sputtering, for example) or a wet plating process. A metal layer may be laminated on a polyimide film by a known method.

A polyimide-metal laminated product may be prepared by laminating a metal foil on one side or both sides of a polyimide film of the present invention, which have an aluminum chelate-modified surface, via a heat-resistant adhesive layer; and continuously pressing, or heating and pressing the polyimide film and the metal foil by a pair of pressing members.

Examples of the pressing member include a pair of press metal rolls in which the press part may be made of either a metal or a ceramic sprayed coating metal, a double-belt press, and a hot-press. A preferable pressing member may be one capable of conducting thermo-compression bonding and cooling under pressure, and a hydraulic-press type double-belt press is particularly preferable.

In the present invention, any of heat-resistant adhesives commonly used in electronics field may be used for adhering a metal foil to a polyimide film, without limitation. Examples of the adhesive include polyimide adhesives, epoxy-modified polyimide adhesives, phenol-modified epoxy resin adhesives, epoxy-modified acrylic resin adhesives, and epoxy-modified polyamide adhesives.

A heat-resistant adhesive layer may be formed by any of methods used in electronics field. For example, an adhesive solution may be applied on the polyimide film, followed by drying. Alternatively, an adhesive film separately formed may be laminated onto the polyimide film.

A metal foil used in the present invention may be made of either a single metal or an alloy. Specific examples of the metal foil include a copper foil, an aluminum foil, a gold foil, a silver foil, a nickel foil and a stainless steel foil. A copper foil such as a rolled copper foil and an electrolytic copper foil may be suitably used. Although there are no particular restrictions to the thickness of the metal foil, it may be preferably 0.1 μm to 10 mm, more preferably 10 μm to 60 μm.

When using an ultrathin copper foil having a thickness of 1 μm to 10 μm as a substrate, a copper foil with a carrier may be suitably used, in view of its superior handling property. Preferable examples of the carrier include, but not limited to, a rolled copper foil and an electrolytic copper foil having a thickness of 5 μm to 150 μm. It is preferable that the carrier can be mechanically peeled from the ultrathin copper foil easily, and a copper foil with a carrier may preferably have a peel strength of 0.01 N/mm to 0.3 N/mm.

Other films or substrates such as a ceramic substrate, a glass substrate, a silicon wafer, a metal or alloy film, a polyimide film, and the like may be attached onto the polyimide-metal laminated product obtained according to the present invention with a heat-resistant adhesive.

A polyimide-metal laminated product may be also prepared by forming a metal layer directly on one side or both sides of the polyimide film of the present invention, which have the aluminum chelate-modified surface, by vapor deposition or sputtering, for example.

A metal layer may be formed on a polyimide film by a physical or chemical vapor deposition method such as vacuum deposition, electron-beam deposition, and sputtering, for example. When a vapor deposition method is employed, the pressure in the system is preferably about 10⁻⁵ Pa to 1 Pa, the deposition rate is preferably about 5 nm/sec to 500 nm/sec, and the temperature of the substrate on which a metal layer is to be formed, i.e. the polyimide film, is preferably about 20° C. to 600° C. When a sputtering method is employed, RF magnetron sputtering is preferable, and the pressure in the system is preferably 100 Pa or less, particularly preferably about 0.1 Pa to 1 Pa, the temperature of the substrate on which a metal layer is to be formed, i.e. the polyimide film, is preferably about 200° C. to 450° C., and the deposition rate (metal layer forming rate) is preferably about 0.05 nm/sec to 50 nm/sec.

Examples of a metal for the metal layer formed on the polyimide film include, but not limited to, copper or alloys of copper, aluminum, tin or alloys of tin, and palladium. The metal layer may comprise an underlayer of chromium, titanium or palladium, and a surface layer of copper, for example.

A thickness of a metal layer formed on a polyimide film may be appropriately determined depending on an intended application, and is typically about 1 μm or less.

Furthermore, a metal-plated layer may be formed on the metal layer thus obtained by a metal plating method such as copper plating. Examples of a metal for the metal-plated layer include, but not limited to, copper or alloys of copper, and silver. A metal-plated layer may be formed either by electrolytic plating or by electroless plating. The thickness of the metal-plated layer may be preferably about 1 μm to 40 μm.

A metal layer may be preferably formed on a polyimide film in a continuous roll to roll process, including sputtering and vapor deposition.

A polyimide-metal laminated product may be also prepared by forming a metal layer on one side or both sides of the polyimide film of the present invention, which have the aluminum chelate-modified surface, by a wet plating process.

There are no particular restrictions to the wet plating process used in the present invention. For example, the following process may be employed.

### Wet Plating Process:

1) Degrease/surface conditioning step: immersion treatment in a surface conditioner at 25° C. to 80° C. for 15 seconds to 30 minutes, for example.

2) Catalyst addition step: treatment with a sensitizer solution, for example, a solution at pH 1 to 5 containing 1 g/L to 50 g/L of a water-soluble stannous salt such as stannous chloride and 5 mL/L to 100 mL/L of an acid such as hydrochloric acid for sensitizing; water washing; and immersion treatment in a catalyst solution, for example, immersion treatment in a palladium activating solution at pH 1 to 5 containing 0.01 g/L to 1 g/L of a water-soluble palladium salt such as palladium chloride and 0.01 mL/L to 1 mL/L of an acid such as hydrochloric acid at 10° C. to 50° C. for 5 seconds to 5 minutes and/or immersion treatment in a silver activating solution at pH 5 to 8 containing 0.1 g/L to 2 g/L of a water-soluble silver salt such as silver nitrate at 10° C. to 50° C. for 5 seconds to 5 minutes for the catalyst addition.

3) Ground layer for electroless plating formation step: immersion treatment in a treatment solution containing 0.001 mol/L to 5 mol/L of zinc ion such as zinc nitrate and 0.00001 mol/L to 0.1 mol/L of indium ion such as indium nitrate at 50° C. to 90° C. for 1 minute or more, to form a zinc-containing indium oxide ground layer.

4) Catalyst addition step: immersion treatment in an aqueous solution at pH 1 to 5 containing 0.01 g/L to 1 g/L of a water-soluble metal salt, for example, a water-soluble palladium salt such as palladium chloride at 10° C. to 80° C. for 5 seconds to 5 minutes; or treatment with the solution by spraying or coating.

5) Electroless metal plating step: immersion treatment in a solution at pH 9 to 14 containing 0.01 mol/L to 0.5 mol/L of a water-soluble metal salt such as copper sulfate, 0.1 mol/L to 1 mol/L of a reducing agent such as formaldehyde and 0.01 mol/L to 1 mol/L of a complexing agent such as EDTA at 10° C. to 70° C. for 5 minutes to 60 minutes.

6) Electrolytic copper plating step: electrolysis using a solution at pH 0.1 to 2 containing 0.1 mol/L to 0.5 mol/L of a water-soluble copper salt such as copper sulfate and 1.5 mol/L to 3 mol/L of an acid such as sulfuric acid, at a cathode current density of 1 A/dm² to 4 A/dm² and at a temperature of 10° C. to 30° C. for 5 minutes to 60 minutes.

One example of the processes is a process in which electrode plating is repeated after forming a ground layer by the “Zintra process” (C. Uyemura & Co., Ltd.) or the “Melplate G/Si process” (Meltex Inc.), for example.

The “Zintra process” yields a metal film having high adhesiveness on a ceramic (soda lime glass), as disclosed in Japanese Laid-open Patent Publication No. 2003-247076. In the “Zintra process”, a catalyst layer containing Sn, Ag and Pd is formed on a base material to be plated by immersing the base material in a chemical solution; a zinc-containing indium hydroxide ground layer is formed thereon by electroless plating; a catalyst metal layer is formed thereon by immersing the laminated material in a treatment solution; and then the laminated material is subjected to electroless copper plating. After electroless copper plating, electrolytic copper plating may be carried out using the copper layer formed by electroless plating as a electrode to achieve the desired thickness.

The “Melplate G/Si process” is a process for plating a ceramic with nickel by electroless plating. After electroless nickel plating, a conductive metal layer may be formed by electroless copper plating and electrolytic copper plating.

A polyimide-copper laminated product may be obtained by modifying the metal oxide-modified surface of an aromatic polyimide film by treatment with a basic amino acid after degrease by alkali treatment; providing the surface with a catalyst for formation of a ground metal layer; forming a nickel ground layer and replacing nickel surface with copper by electroless copper displacement plating; and forming a conductive metal layer by electrolytic copper plating using the nickel ground layer including the copper displacement plated layer as a electrode, as disclosed in Japanese Laid-open Patent Publication No. 2007-56343.

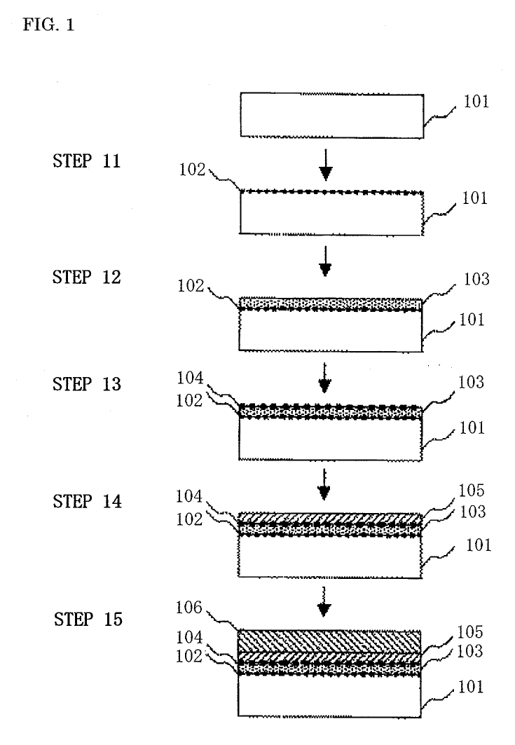

An example of the typical process for producing the polyimide-metal laminated product of the present invention will now be described with reference to FIG. 1.

In FIG. 1, 101 is the polyimide film of the present invention (polyimide film having an aluminum chelate-modified surface). In step 11, a catalyst for ground layer formation 102 is added after an ordinary degrease/washing treatment, and in step 12, a zinc-containing indium hydroxide ground layer 103 is formed by electroless plating. And then, in step 13, a catalyst for electroless copper plating 104 is added, and in step 14, an electrode layer for electrolytic copper plating 105 is formed by electroless copper plating. Subsequently, in step 15, a conductive metal layer 106 is formed by electrolytic copper plating, to prepare a polyimide-copper laminated product. All steps 11 to 15 are wet processes.

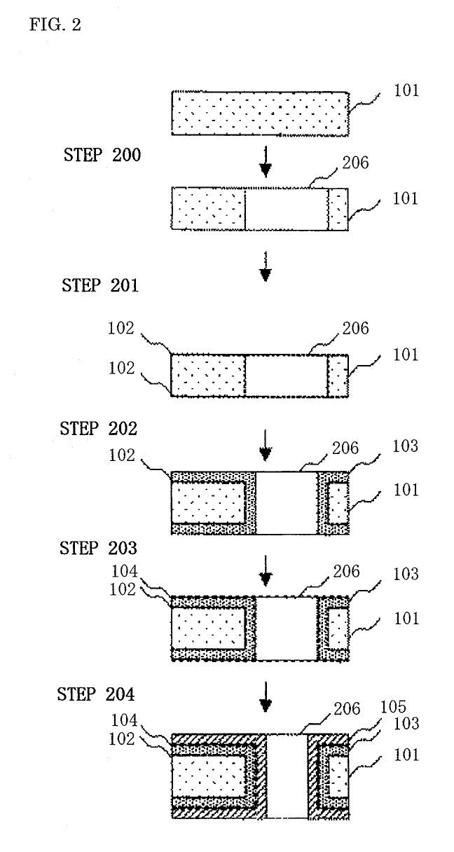

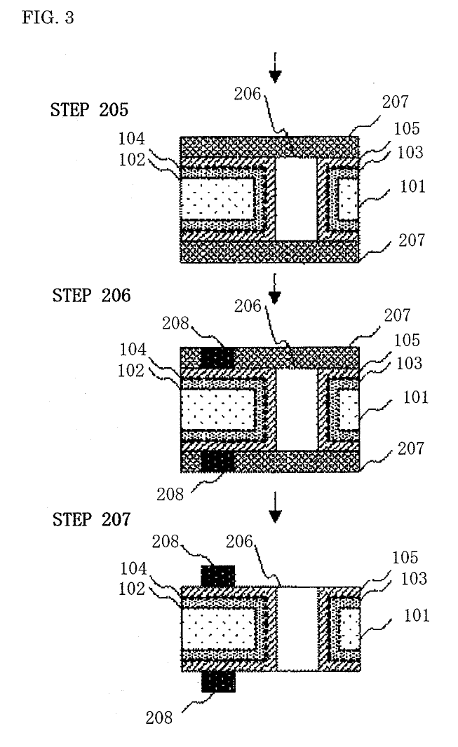

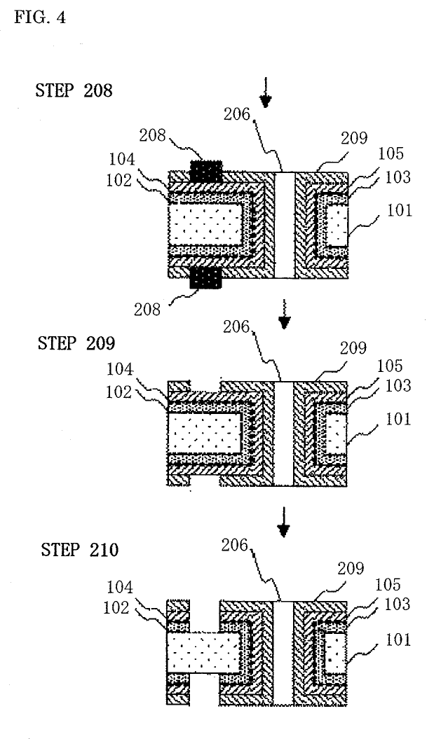

An example of the typical process for producing the polyimide double-sided circuit board of the present invention will now be described with reference to FIGS. 2 to 4. This is an example of batch formation of a double-sided circuit. The reference numerals 101 to 105 in FIGS. 2 to 4 are the same as in FIG. 1.

First, in step 200, a through-hole 206 is formed in the film 101 to allow front/back conduction. The hole may be formed by any of methods capable of front/back perforation, such as punching and laser processing. Steps 201 to 204 are the same as in FIG. 1 except that both sides of the board and the through-holes are simultaneously treated, and correspond to steps 11 to 14, respectively.

In step 205, a dry film type negative photoresist 207 is attached to the front and back sides of the polyimide base material having the electrode layer for electrolytic copper plating 105 on both sides thereof and the through-holes. And then, in step 206, a circuit pattern on the mask is transferred to the photoresist by light exposure and the section in which a circuit is not formed (non-circuit-forming section) 208 is exposed. And then, in step 207, the unexposed resist in the circuit-forming section is removed by development.

Although a negative-type dry film photoresist is used in the above example so as to obtain a thick circuit easily, a positive-type photoresist may be used. When using a positive-type photoresist, the circuit-forming section is exposed. A liquid photoresist may be also used, so long as the required thickness is achieved.

Then, in step 208, a conductive layer 209 is formed by electrolytic copper plating on the section in which the resist has been removed for formation of a circuit. And then, in step 209, the resist is removed with an alkali solution, for example. Finally, in step 210, the electroless copper plated layer (copper layer formed by electroless plating) and the ground layer in the non-circuit-forming section are removed by microetching, for example, to prepare a double-sided polyimide circuit board.

All steps except steps 206 and 207 are wet processes.

Although a copper layer is formed in the above example, any metal layer may be formed as a conductive layer, so long as the metal is suitable for wet plating. In addition, although an electroless copper plated layer is formed as a conductive layer for electrolytic copper plating in the above example so as to obtain a good conductive layer having an adequate thickness, electroless plating may be employed alone without electrolytic plating, electrolytic plating may be carried out using the ground layer as a conductive layer, and the metal contained in the electrolytic plated layer may be different from the metal contained in the conductive metal layer formed by electroless plating which is an electrode layer for electrolytic plating, according to the required performance. When using the process in which formation of a ground layer is dispensable for plating a ceramic, a ground layer may not be formed in the present invention.

Although a conductive layer (metal layer) is formed by a wet plating process in the above example, the conductive layer may be formed by a dry plating process (metal vapor deposition or sputtering, for example).

### EXAMPLES

The present invention will be described in more detail below with reference to the Examples. However, the present invention is not limited to these Examples.

Evaluation Method

The aluminum content of a surface of a polyimide film was measured by the scanning X-ray photoelectron spectrometer Quantum 2000 manufactured by PHI.

The electron microscopic observation of a surface of a polyimide film was carried out under the conditions of a accelerating voltage of 10 kV and a degree of vacuum of 1×10⁻³ MPa, using the electron microscope JSM-6460LA manufactured by JEOL, after the polyimide film surface to be observed was treated with a metal oxide.

The mechanical strength of a polyimide film was measured by TENSILON AR6000 series, the universal tensile tester UTM-II-20 and the flat-type automatic balancing recorder R-840 manufactured by ORIENTEC Co., Ltd under the conditions of a distance between chucks of 30 mm and a tensile speed of 2 mm/min, using a sample piece with a width of 4 mm.

The 90° peel strength of a polyimide-metal laminated product was measured by TENSILON AR6000 series, the universal tensile tester UTM-II-20 and the flat-type automatic balancing recorder R-840 manufactured by ORIENTEC Co., Ltd under the conditions of a peel speed of 40 mm/min, using a sample piece with a width of 1 cm.

### Reference Example 1

### Preparation of the Application Solution

Into a sample vessel were placed 3.80 g of aluminum tris(ethylacetoacetate), 0.20 g of aluminum ethylacetoacetate diisopropylate (ALCH), 0.03 g of water, 0.10 g of silicone surfactant (FZ-2101 made by Dow Corning Toray Co., Ltd.), and 96.00 g of N,N-dimethylacetamide (DMAc), and the resulting mixture was homogeneously mixed to obtain the application solution 1.

### Reference Examples 2-12

### Preparation of the Application Solution

The application solutions 2-12 which have the compositions shown in Table 1, respectively, were prepared in the same way as in Reference Example 1.

TABLE 1

| | Aluminum chelate compound | | ALCH | Water | FZ-2101 | EG | Solvent | |
|---|---|---|---|---|---|---|---|---|
| | compound | (g) | (g) | (g) | (g) | (g) | compound | (g) |
| Application solution 1 | aluminum tris(ethylacetoacetate) | 3.80 | 0.20 | 0.03 | 0.10 | — | DMAc | 96.00 |
| Application solution 2 | ALCH-TB | 3.80 | 0.20 | 0.03 | 0.10 | — | DMAc | 96.00 |
| Application solution 3 | ALCH-TB | 4.00 | — | — | 0.10 | — | DMAc | 96.00 |
| Application solution 4 | aluminum tris(methylacetoacetate) | 3.80 | 0.20 | 0.03 | 0.10 | — | DMAc | 96.00 |
| Application solution 5 | aluminum tris(sec-butylacetoacetate) | 3.80 | 0.20 | 0.03 | 0.10 | — | DMAc | 96.00 |
| Application solution 6 | aluminum tris(hexylacetoacetate) | 3.80 | 0.20 | 0.03 | 0.10 | — | DMAc | 96.00 |
| Application solution 7 | aluminum tris(iso-octylacetoacetate) | 3.80 | 0.20 | 0.03 | 0.10 | — | DMAc | 96.00 |
| Application solution 8 | ALCH-TB | 3.92 | 0.08 | 0.01 | — | — | IPA | 96.00 |
| Application solution 9 | aluminum tris(ethylacetoacetate) | 3.80 | 0.20 | 0.03 | — | 9.60 | DMAc | 86.40 |
| Application solution 10 | aluminum tris(ethylacetoacetate) | 3.80 | 0.20 | 0.03 | 0.005 | — | DMAc | 96.00 |
| Application solution 11 | — | — | 4.00 | — | 0.10 | — | DMAc | 96.00 |
| Application solution 12 | aluminum tris(ethylacetoacetate) | 3.80 | — | — | — | — | DMAc | 96.00 |

In Table 1, ALCH-TB is the aluminum chelate compound represented by the formula (1) in which R₁, R₂ and R₃ are ethyl or isobutyl, made by Kawaken Fine Chemicals Co., Ltd., ALCH is aluminum ethylacetoacetate diisopropylate, EG is ethylene glycol, DMAc is N,N-dimethylacetamide, and IPA is isopropyl alcohol.

### Reference Example 13

### Preparation of the Application Solution

Into a sample vessel were placed 3.80 g of aluminum tris(ethylacetoacetate), 0.20 g of aluminum hexylacetoacetate diisopropylate, 0.03 g of water, 0.10 g of silicone surfactant (FZ-2101 made by Dow Corning Toray Co., Ltd.), and 96.00 g of N,N-dimethylacetamide (DMAc), and the resulting mixture was homogeneously mixed to obtain the application solution 13.

### Reference Example 14

### Preparation of the Polyamic Acid Solution A

The polyamic acid solution was prepared as follows.

Into a 300 mL-volume glass reactor equipped with a stirrer, a nitrogen gas feed pipe and a reflux condenser were placed 183 g of N,N-dimethylacetamide (DMAc), 0.1 g of triethanolamine salt of monostearyl phosphate, and 0.1 g (solid content) of colloidal silica (average particle size: 0.08 μm). And then, 10.81 g of p-phenylenediamine was added to the resulting mixture while stirring under a nitrogen stream, and was warmed at 50° C. to give a homogeneous solution. Subsequently, 29.229 g of 3,3′,4,4′-biphenyltetracarboxylic dianhydride (s-BPDA) was gradually added to the resulting solution, and reacted at 50° C. for 5 hours. And then, 0.2381 g of 3,3′,4,4′-biphenyltetracarboxylic acid dihydrate was added and dissolved in the resulting solution. To the resulting solution was added 0.961 g of 1,2-dimethylimidazole, and the resulting mixture was stirred to give a homogeneous solution.

The polyamic acid solution A (polyimide precursor solution) thus obtained was a brown viscous liquid, and had a solution viscosity at 25° C. of about 1800 poise.

### Reference Example 15

### Preparation of the Polyamic Acid Solution B

The polyamic acid solution was prepared as follows.

Into a 300 mL-volume glass reactor equipped with a stirrer, a nitrogen gas feed pipe and a reflux condenser were placed 183 g of N,N-dimethylacetamide (DMAc), 0.1 g of triethanolamine salt of monostearyl phosphate, and 0.1 g (solid content) of colloidal silica (average particle size: 0.08 μm). And then, 10.81 g of p-phenylenediamine was added to the resulting mixture while stirring under a nitrogen stream, and was warmed at 50° C. to give a homogeneous solution. Subsequently, 29.229 g of 3,3′,4,4′-biphenyltetracarboxylic dianhydride (s-BPDA) was gradually added to the resulting solution, and reacted at 50° C. for 5 hours. And then, 0.2381 g of 3,3′,4,4′-biphenyltetracarboxylic acid dihydrate was added and dissolved in the resulting solution.

The polyamic acid solution B (polyimide precursor solution) thus obtained was a brown viscous liquid, and had a solution viscosity at 25° C. of about 1500 poise.

### Examples 1-13

### Preparation of the Polyimide Film Having an Aluminum Chelate-Modified Surface

The polyamic acid solution A or the polyamic acid solution B shown in Table 3 was flow-casted on a glass plate and heated at 135° C. for 3 min for drying. And then, the dried film was peeled off from the support (glass plate) to give a self-supporting film.

The self-supporting film obtained was fixed on a frame and the application solution shown in Table 3 the composition of which is shown in Table 1 was applied onto the self-supporting film. The application amount was 5 g/m². And then, the self-supporting film was fed into a continuous heating oven, and the film was heated from 120° C. to the highest heating temperature of 450° C. in the oven to effect imidization, thereby producing a polyimide film with a thickness of about 25 μm having an aluminum chelate-modified surface (Samples 1-13) shown in Table 3.

In Example 12, the highest heating temperature in the heat treatment for imidization was changed to 500° C.

In Example 13, the highest heating temperature in the heat treatment for imidization was changed to 520° C.

Evaluation of the Surface and Mechanical Properties of Sample 1

The aluminum content of the aluminum chelate-modified surface of the polyimide film prepared in Example 1 (Sample 1) was measured by a scanning X-ray photoelectron spectrometer. The result of the measurement was 5.77% in terms of aluminum atom.

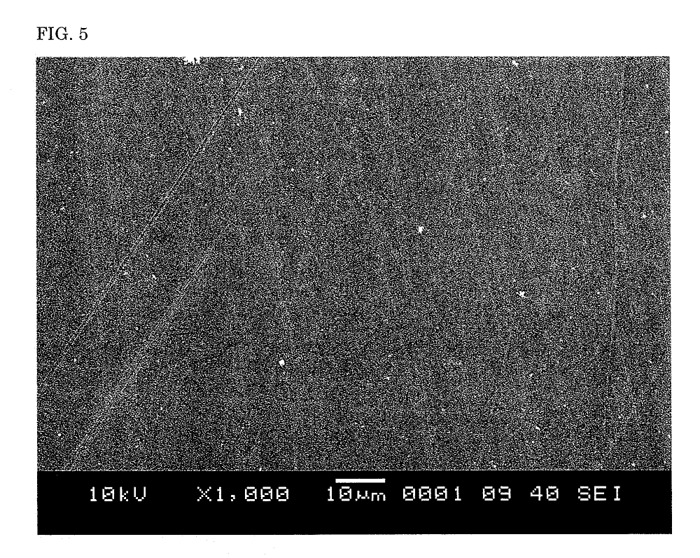

FIG. 5 is the electron microscope photograph of the aluminum chelate-modified surface of the polyimide film. From the electron microscopic observation (magnification: 1000×), characteristic reticulated irregularities were not observed on the aluminum chelate-modified surface.

The mechanical strength of the polyimide film was a tensile strength of 390 MPa, a tensile elongation of 28.5%, and a tensile elastic modulus of 8.7 GPa.

Evaluation of the Surface Properties of Samples 1-13

The aluminum chelate-modified surfaces of the polyimide films prepared in Examples 1-13 (Samples 1-13) were observed with an optical microscope at a magnification of 500 times. From the observations, characteristic reticulated irregularities were not observed on the aluminum chelate-modified surfaces of all of the polyimide films, as the electron microscope photograph at a magnification of 1000 times shown as FIG. 5.

Production of the Polyimide-Metal Laminated Product by a Wet Plating Process

The polyimide-metal laminated products were produced from the polyimide films having an aluminum chelate-modified surface (Samples 1-13) as follows. In these Examples, a metal thin film was formed on the aluminum chelate-modified surface by a wet plating process.

First, a ground layer and an electroless copper plated layer (copper layer formed by electroless copper plating) were formed on the aluminum chelate-modified surface of the polyimide film by the plating process (“Zintra process”, C. Uyemura & Co., Ltd.) as shown in Table 2. Subsequently, electrolytic copper plating was carried out for 30 minutes at a current density of 3 A/dm², using a copper sulfate-based electrolytic plating solution. The laminate thus obtained was heated at 200° C. for 60 minutes, and then at 150° C. for 24 hours to obtain a polyimide-metal laminated product with a copper thickness of 10 μm (Plated Samples 1-13).

The 90° peel strength and the 90° peel strength after heat treatment at 150° C. for 168 hours of the polyimide-metal laminated products (Plated Samples 1-13) were measured. The results are shown in Table 4.

TABLE 2

| Step | | Chemical agent | Temp. | Time | |
|---|---|---|---|---|---|
| Degrease/surface | (1) | Zintra MTL-50 | 50° C. | 5 | min. |
| conditioning | | | | | |
| Catalyst addition | (2) | Zintra MTS-17 | 25° C. | 30 | sec. |
| | (3) | Activator MSA-27 | 25° C. | 30 | sec. |
| | (4) | Activator A-10X | 25° C. | 30 | sec. |
| | Repeating (2) to (4) | | | | |
| Electroless oxide | (5) | Zintra HMT-70 | 80° C. | 2.5 | min. |
| Catalyst addition | (6) | Zintra MTS-17 | 25° C. | 30 | sec. |
| | (7) | Activator A-10X | 25° C. | 30 | sec. |
| Electroless copper | (8) | Thru-Cup PEA | 36° C. | 15 | min. |

### Comparative Example 1

### Preparation of the Polyimide Film Having an Aluminum Chelate-Modified Surface

A polyimide film having an aluminum chelate-modified surface was prepared in the same way as in Example 1, except that the application solution 11 shown in Table 1 was applied onto the self-supporting film, instead of the application solution 1.

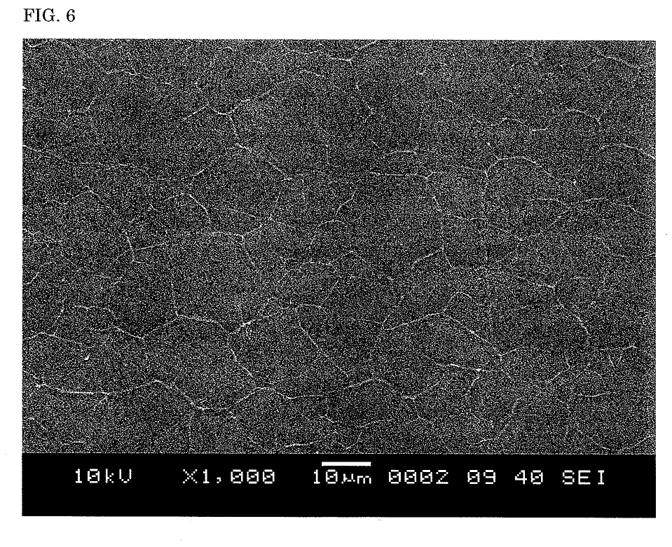

FIG. 6 is the electron microscope photograph of the aluminum chelate-modified surface of the polyimide film. From the electron microscopic observation (magnification: 1000×), characteristic reticulated irregularities were observed on the aluminum chelate-modified surface.

### Comparative Example 2

### Preparation of the Polyimide Film Having an Aluminum Chelate-Modified Surface

A self-supporting film of a polyimide precursor solution was prepared in the same way as in Example 1, and the application solution 12 shown in Table 1 was applied onto the self-supporting film. The application solution 12 was repelled and was not applied uniformly and evenly.

TABLE 3

| | | | Aluminum chelate-modified polyimide film | |
|---|---|---|---|---|
| | | | | Optical microscopic observation of |
| | Polyamic acid | Application solution | | Aluminum chelate-modified surface |
| Example 1 | Polyamic acid A | Application solution 1 | Sample 1 | No reticulated irregularities |
| Example 2 | Polyamic acid A | Application solution 2 | Sample 2 | No reticulated irregularities |
| Example 3 | Polyamic acid A | Application solution 3 | Sample 3 | No reticulated irregularities |
| Example 4 | Polyamic acid A | Application solution 4 | Sample 4 | No reticulated irregularities |
| Example 5 | Polyamic acid A | Application solution 5 | Sample 5 | No reticulated irregularities |
| Example 6 | Polyamic acid A | Application solution 6 | Sample 6 | No reticulated irregularities |
| Example 7 | Polyamic acid A | Application solution 7 | Sample 7 | No reticulated irregularities |
| Example 8 | Polyamic acid A | Application solution 8 | Sample 8 | No reticulated irregularities |
| Example 9 | Polyamic acid A | Application solution 9 | Sample 9 | No reticulated irregularities |
| Example 10 | Polyamic acid B | Application solution 10 | Sample 10 | No reticulated irregularities |
| Example 11 | Polyamic acid B | Application solution 13 | Sample 11 | No reticulated irregularities |
| Example 12 | Polyamic acid B | Application solution 1 | Sample 12 | No reticulated irregularities |
| Example 13 | Polyamic acid B | Application solution 1 | Sample 13 | No reticulated irregularities |
| Comparative Example 1 | Polyamic acid A | Application solution 11 | Sample 14 | Reticulated irregularities observed |
| Comparative Example 2 | Polyamic acid A | Application solution 12 | — | — |

TABLE 4

| | | Wet-Plated Sample | |
|---|---|---|---|
| | | 90° peel | |
| | Polyimide film | strength | 90° peel strength after heating |
| | to be plated | (N/mm) | at 150° C. for 168 hours (N/mm) |
| Example 1 | Sample 1 | 0.54 | 0.48 |
| Example 2 | Sample 2 | 0.60 | 0.50 |
| Example 3 | Sample 3 | 0.60 | 0.40 |
| Example 4 | Sample 4 | 0.40 | 0.30 |
| Example 5 | Sample 5 | 0.30 | 0.14 |
| Example 6 | Sample 6 | 0.50 | 0.08 |
| Example 7 | Sample 7 | 0.40 | 0.14 |
| Example 8 | Sample 8 | 0.40 | 0.30 |
| Example 9 | Sample 9 | 0.78 | 0.75 |
| Example 10 | Sample 10 | 1.00 | 0.90 |
| Example 11 | Sample 11 | 0.52 | 0.18 |
| Example 12 | Sample 12 | 0.38 | 0.14 |
| Example 13 | Sample 13 | 0.30 | 0.06 |

The characteristic reticulated irregularities were observed by optical microscopic observation at a magnification of 500 times on the aluminum chelate-modified surface (surface to which the solution containing the aluminum chelate compound was applied) of the polyimide film prepared in Comparative Example 1, as the electron microscope photograph at a magnification of 1000 times shown as FIG. 6. Consequently, it is expected that when using the polyimide film for the formation of a fine-pitch circuit, undesired copper remains or the corrosion of wiring occurs after etching, and an electronic circuit having high electrical reliability may not be obtained.

In contrast, the characteristic reticulated irregularities were not observed by optical microscopic observation at a magnification of 500 times on the aluminum chelate-modified surfaces (surface to which the solution containing the aluminum chelate compound was applied) of the polyimide films prepared in Examples 1-13, as the electron microscope photograph at a magnification of 1000 times shown as FIG. 5. Consequently, it is expected that when using the polyimide film for the formation of a fine-pitch circuit, undesired copper does not remain, or seldom, if ever, and the corrosion of wiring hardly occur after etching, and an electronic circuit having high electrical reliability may be obtained.

Production of the Polyimide-Metal Laminated Product by the Use of an Adhesive

The polyimide-metal laminated product was produced from the polyimide film prepared in Example 1 (Sample 1) as follows. In this Example, a metal foil was laminated on the aluminum chelate-modified surface via an adhesive sheet.

An adhesive sheet (Pyralux LF made by Du Pont) and a electrolytic copper foil (BHY-13H-T made by Nippon Mining & Metals Co., Ltd., thickness: 18 μm) were laminated on the aluminum chelate-modified surface of the polyimide film (Sample 1), and the laminate was pressed by a pressure of 3 MPa at a temperature of 180° C. for 5 minutes, and then heated at 180° C. for 1 hour in a hot air oven to obtain a polyimide-metal laminated product.

The 90° peel strength of the polyimide-metal laminated product was 1.5 N/mm.

Production of the Circuit Board 1

The circuit board was obtained by forming a circuit by a semi-additive process after forming a copper thin film by the wet plating process.

A dry film type photoresist with a thickness of 15 μm (SPG-152 made by Asahi Kasei Corporation) was laminated onto the copper-plated polyimide film prepared in Example 1 (Plated Sample 1) at a temperature of 70° C. and a pressure of 0.45 MPa, and a pattern with a pitch of 30 μm was exposed with 160 mJ using a projection exposure machine. And then, spray development was carried out under a pressure of 0.2 MPa for 30 seconds using 1% sodium carbonate aqueous solution at 30° C. to remove the photoresist in the circuit-forming section. After an ordinary acid degrease and acid washing, electrolytic copper plating was carried out for 30 minutes at a current density of 2 A/dm² using a copper sulfate-based plating solution to form a circuit pattern with a copper thickness of 8 μm. Then, the dry film type photoresist was stripped off using 1% sodium hydroxide aqueous solution. Subsequently, an iron chloride-based soft-etching solution (C-800 made by ADEKA CORPORATION) was sprayed under a pressure of 0.05 MPa for 1 minute to remove the electroless copper plated layer and the ground layer in the non-circuit-forming section, to obtain a polyimide circuit board.

For the polyimide circuit board thus obtained, a pattern peeling test was carried out using a Scotch tape made by Sumitomo 3M Limited. The observation by a stereoscopic microscope at a magnification of 20 times revealed that a pattern was not peeled off.

Production of the Polyimide-Metal Laminated Product by a Dry Plating Process

The polyimide-metal laminated product was produced from the polyimide film prepared in Example 1 (Sample 1) as follows. In this Example, a metal thin film was formed on the aluminum chelate-modified surface by a dry plating process.

First, the polyimide film (Sample 1) was placed on a substrate holder in a sputtering apparatus, and then the sputtering apparatus was evacuated to 2×10⁻⁴ Pa or less. Subsequently, argon was introduced into the sputtering apparatus so that the pressure therein was 0.67 Pa, a high-frequency power of 13.56 MHz and 300 W was applied to the electrode, and thereby the aluminum chelate-modified surface of the polyimide film was cleaned by plasma treatment for 10 minutes. And then, under an argon atmosphere of 0.67 Pa, a NiCr thin film with a thickness of 15 nm was formed on the aluminum chelate-modified surface, and a copper thin film with a thickness of 0.4 μm was formed thereon. Then, the copper-laminated polyimide film was taken out in an atmosphere. Subsequently, electrolytic copper plating was carried out using an acid copper sulfate aqueous solution as a plating solution to obtain a polyimide-metal laminated product with a metal thickness of 20 μm.

The 90° peel strength of the polyimide-metal laminated product was 1.35 N/mm. The 90° peel strength after heat treatment at 150° C. for 24 hours of the polyimide-metal laminated product was 0.57 N/mm.

Production of the Circuit Board 2

The circuit board was obtained by forming a circuit by a semi-additive process after forming a copper thin film by the dry plating process.

First, the polyimide film (Sample 1) was placed on a substrate holder in a sputtering apparatus, and then the sputtering apparatus was evacuated to 2×10⁻⁴ Pa or less. Subsequently, argon was introduced into the sputtering apparatus so that the pressure therein was 0.67 Pa, a high-frequency power of 13.56 MHz and 300 W was applied to the electrode, and thereby the aluminum chelate-modified surface of the polyimide film was cleaned by plasma treatment for 10 minutes. And then, under an argon atmosphere of 0.67 Pa, a NiCr thin film with a thickness of 15 nm was formed on the aluminum chelate-modified surface, and a copper thin film with a thickness of 0.4 μm was formed thereon. Then, the copper-laminated polyimide film was taken out in an atmosphere.

A dry film type photoresist with a thickness of 15 μm (SPG-152 made by Asahi Kasei Corporation) was laminated onto the copper-laminated polyimide film thus obtained at a temperature of 70° C. and a pressure of 0.45 MPa, and a pattern with a pitch of 30 μm was exposed with 160 mJ using a projection exposure machine. And then, spray development was carried out under a pressure of 0.2 MPa for 30 seconds using 1% sodium carbonate aqueous solution at 30° C. to remove the photoresist in the circuit-forming section. After an ordinary acid degrease and acid washing, electrolytic copper plating was carried out for 30 minutes at a current density of 2 A/dm² using a copper sulfate-based plating solution to form a circuit pattern with a copper thickness of 8 μm. Then, the dry film type photoresist was stripped off using 1% sodium hydroxide aqueous solution. Subsequently, an iron chloride-based soft-etching solution (C-800 made by ADEKA CORPORATION) was sprayed under a pressure of 0.05 MPa for 1 minute to remove the electroless copper layer in the non-circuit-forming section, and then it was immersed in a chemical solution (FLICKER-MH made by NIHON KAGAKU SANGYO CO., LTD.) at a temperature of 45° C. for 5 minutes to remove the NiCr layer in the non-circuit-forming section, to obtain a polyimide circuit board.

For the polyimide circuit board thus obtained, a pattern peeling test was carried out using a Scotch tape made by Sumitomo 3M Limited. The observation by a stereoscopic microscope at a magnification of 20 times revealed that a pattern was not peeled off.

### INDUSTRIAL APPLICABILITY

As described above, a polyimide film obtained according to the present invention may have excellent adhesive properties, sputtering property, metal vapor deposition property and metal plating property, and excellent surface smoothness, while maintaining the excellent properties of a polyimide film.

1. A process for producing a polyimide film, comprising steps of:
providing a self-supporting film of a polyimide precursor solution;
applying a solution containing an aluminum chelate compound onto one side or both sides of the self-supporting film; and
heating the self-supporting film onto which the aluminum chelate compound solution is applied to effect imidization;
wherein the aluminum chelate compound is a compound represented by the formula (1): 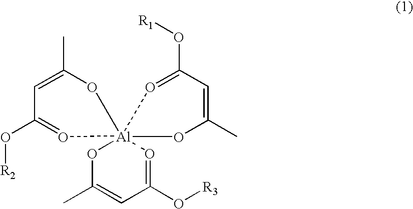
wherein R₁, R₂ and R₃ independently represent a linear or branched alkyl group having 1 to 8 carbon atoms.

2. The process for producing a polyimide film as claimed in claim 1, wherein the aluminum chelate compound solution to be applied onto one side or both sides of the self-supporting film contains a nonionic surfactant.

3. The process for producing a polyimide film as claimed in claim 2, wherein the nonionic surfactant contained in the aluminum chelate compound solution is at least one selected from the group consisting of silicone surfactants and polyethylene glycol surfactants.

4. The process for producing a polyimide film as claimed in claim 1, wherein the aluminum chelate compound solution to be applied onto one side or both sides of the self-supporting film contains an aluminum alcoholate compound having at least one alkoxy group.

5. The process for producing a polyimide film as claimed in claim 4, wherein the aluminum alcoholate compound contained in the aluminum chelate compound solution is a compound represented by the formula (2): 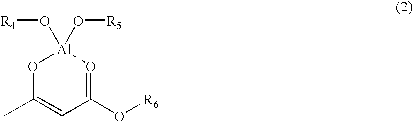
wherein
R₄ and R₅ independently represent a linear or branched alkyl group having 1 to 6 carbon atoms, and
R₆ represents a linear or branched alkyl group having 1 to 8 carbon atoms.

6. The process for producing a polyimide film as claimed in claim 4, wherein the aluminum alcoholate compound contained in the aluminum chelate compound solution is aluminum ethylacetoacetate diisopropylate.

7. The process for producing a polyimide film as claimed in claim 4, wherein the aluminum chelate compound is aluminum tris(ethylacetoacetate).

8. The process for producing a polyimide film as claimed in claim 1, wherein the self-supporting film is heated to the highest heating temperature of from 350° C. to 520° C. for imidization.

9. A polyimide film produced by the process as claimed claim 1.

10. A polyimide film wherein the aluminum content of at least one surface of the polyimide film is within a range of 0.1% to 52%; and reticulated irregularities is not observed in the surface with an optical microscope at a magnification of 500 times.

11. A polyimide-metal laminated product wherein a metal layer is formed on the surface of the polyimide film as claimed in claim 9 onto which a solution containing an aluminum chelate compound represented by the formula (1) is applied in producing the polyimide film.

12. The polyimide-metal laminated product as claimed in claim 11, wherein the metal layer is formed on the polyimide film by adhering a metal foil with an adhesive.

13. The polyimide-metal laminated product as claimed in claim 11, wherein the metal layer is formed on the polyimide film by a dry plating process or a wet plating process.

14. A circuit board obtained by forming a circuit on the polyimide-metal laminated product as claimed in claim 11.

15. The circuit board as claimed in claim 14, wherein the circuit board comprises a metal wiring with a pitch of 30 μm or less.

16. The process for producing a polyimide film as claimed in claim 1, wherein the aluminum chelate compound is aluminum tris(ethylacetoacetate).

17. The process for producing a polyimide film as claimed in claim 2, wherein the aluminum chelate compound is aluminum tris(ethylacetoacetate).
